(19) United States
(12) Patent Application Publication
(10) Pub. No.: US 2008/0111187 A1
(43) Pub. Date: May 15, 2008

(54) SEMICONDUCTOR MEMORY DEVICE AND MANUFACTURING METHOD THEREOF

(75) Inventor: Yoshihiro MINAMI, Yokosuka-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/939,203

(22) Filed: Nov. 13, 2007

(30) Foreign Application Priority Data
Nov. 14, 2006 (JP) 2006-307672

(51) Int. Cl. H01L 29/786; H01L 21/336

(52) U.S. Cl. 257/347; 438/151; 257/E21.411; 257/E29.273

(57) ABSTRACT

This disclosure concerns a semiconductor memory device comprising a semiconductor substrate; a buried insulating film provided on the semiconductor substrate; a semiconductor layer provided on the buried insulating film; an N-type source layer formed in the semiconductor layer; an N-type drain layer formed in the semiconductor layer; a body region formed in the semiconductor layer to be provided between the source layer and the drain layer, the body region being in an electrically floating state and holding data according to a state of accumulating majority carriers in the body region; a gate insulating film provided on the body region; a gate electrode provided on the gate insulating film; and a P-type diffusion layer provided on a surface of the semiconductor substrate present under the drain layer, wherein a conduction type of a surface of the semiconductor substrate present under the body region is an N type.

### CROSS-REFERENCE TO RELATED APPLICATION

This application is based upon and claims the benefit of priority from the prior Japanese Patent Application No. 2006-307672, filed on Nov. 14, 2006, the entire contents of which are incorporated herein by reference.

### BACKGROUND OF THE INVENTION

1. Field of the Invention

The present invention relates to a semiconductor memory device and a manufacturing method thereof.

2. Related Art

In recent years, an FBC memory device is expected to replace a DRAM as a semiconductor memory device. The FBC memory device is configured so that FETs (Field Effect Transistors) each including a floating body (hereinafter, also “body region”) are formed on an SOI (Silicon On Insulator) substrate, and so that data “1” or “0” is stored in each of the FETs according to the number of majority carriers accumulated in the body region.

In the FBC memory device, it is desirable that a capacity between the body region and the substrate is larger so as to increase a signal difference between the data “0” and “1”. With a view of increasing the signal difference between the data “0” and “1”, therefore, it is preferable to make a BOX (Buried Oxide) layer included in the SOI substrate thinner.

However, if the BOX layer is thinner, both the capacity between a source layer of each FET and the substrate and that between a drain layer thereof and the substrate become larger. Due to this, a bit line capacity is substantially increased and it takes longer time to raise a potential of drain layers. As a result, an operating rate for turning on or off the FBC memory device is disadvantageously decelerated.

To deal with the disadvantage, a structure in which a bottom of the body region protrudes in a convex manner toward a supporting substrate is disclosed in JP-A 2003-168802 (KOKAI) (Patent Document 1). However, the structure has a disadvantage of high cost because of the complicated manufacturing process for the structure.

### SUMMARY OF THE INVENTION

A semiconductor memory device according to an embodiment of the present invention comprises a semiconductor substrate; a buried insulating film provided on the semiconductor substrate; a semiconductor layer provided on the buried insulating film; an N-type source layer formed in the semiconductor layer; an N-type drain layer formed in the semiconductor layer; a body region formed in the semiconductor layer to be provided between the source layer and the drain layer, the body region being in an electrically floating state and holding data according to a state of accumulating majority carriers in the body region; a gate insulating film provided on the body region; a gate electrode provided on the gate insulating film; and a P-type diffusion layer provided on a surface of the semiconductor substrate present under the drain layer, wherein a conduction type of a surface of the semiconductor substrate present under the body region is an N type.

A semiconductor memory device according to an embodiment of the present invention comprises a P-type semiconductor substrate; a buried insulating film provided on the semiconductor substrate; a semiconductor layer provided on the buried insulating film; an N-type source layer formed in the semiconductor layer; an N-type drain layer formed in the semiconductor layer; a body region formed in the semiconductor layer to be provided between the source layer and the drain layer, the body region being in an electrically floating state and holding data according to a state of accumulating majority carriers in the body region; a gate insulating film provided on the body region; a gate electrode provided on the gate insulating film; and a P-type diffusion layer provided on a surface of the semiconductor substrate present under the drain layer, the P-type diffusion layer being lower in impurity concentration than the semiconductor substrate, wherein a conduction type of a surface of the semiconductor substrate present under the body region is same conduction type as the other part of the semiconductor substrate.

A method of manufacturing a semiconductor memory device according to an embodiment of the present invention comprises preparing a semiconductor substrate including a semiconductor substrate, a buried insulating film provided on the semiconductor substrate, and a semiconductor layer provided on the buried insulating film; forming a gate insulating film on the semiconductor layer; depositing a gate electrode material on the gate insulating film; depositing a mask material on the gate electrode material; working the mask material into a gate electrode pattern; forming a gate electrode by etching the gate electrode material using the mask material as a mask; forming a diffusion layer in the semiconductor substrate in a self-aligned fashion by implanting an impurity into a surface of the semiconductor substrate using the mask material or the gate electrode as a mask; and forming a source layer and a drain layer in the semiconductor layer in a self-aligned fashion by implanting an impurity opposite in conduction type to the impurity of the diffusion layer into the semiconductor layer using the gate electrode as a mask.

### BRIEF DESCRIPTION OF THE DRAWINGS

FIG. 1 is a plan view of an FBC memory device 100 according to a first embodiment of the present invention;

FIG. 2 is a cross-sectional view of the FBC memory device 100 taken along a line 2-2 of FIG. 1;

FIG. 3 is a cross-sectional view of the FBC memory device 100 taken along a line 3-3 of FIG. 1;

FIG. 4 is a cross-sectional view of the FBC memory device 100 taken along a line 4-4 of FIG. 1;

FIGS. 5 to 9 are cross-sectional views showing the method of manufacturing the FBC memory device 100 according to the first embodiment;

FIG. 10 is a cross-sectional view of an FBC memory device 200 according to a second embodiment of the present invention;

FIG. 11 is a plan view of an FBC memory device 300 according to a third embodiment of the present invention;

FIG. 12 is a cross-sectional view of the FBC memory device 300 taken along a line 12-12 of FIG. 11;

FIG. 13 is a cross-sectional view of the FBC memory device 300 taken along a line 13-13 of FIG. 11;

FIG. 14 is a cross-sectional view of the FBC memory device 300 taken along a line 14-14 of FIG. 11; and

FIG. 15 is a cross-sectional view of the FBC memory device having the capacity adjustment layers 90 under only the drain 50.

### DETAILED DESCRIPTION OF THE INVENTION

Embodiments of the present invention will be explained below in detail with reference to the accompanying drawings. Note that the invention is not limited thereto.

### FIRST EMBODIMENT

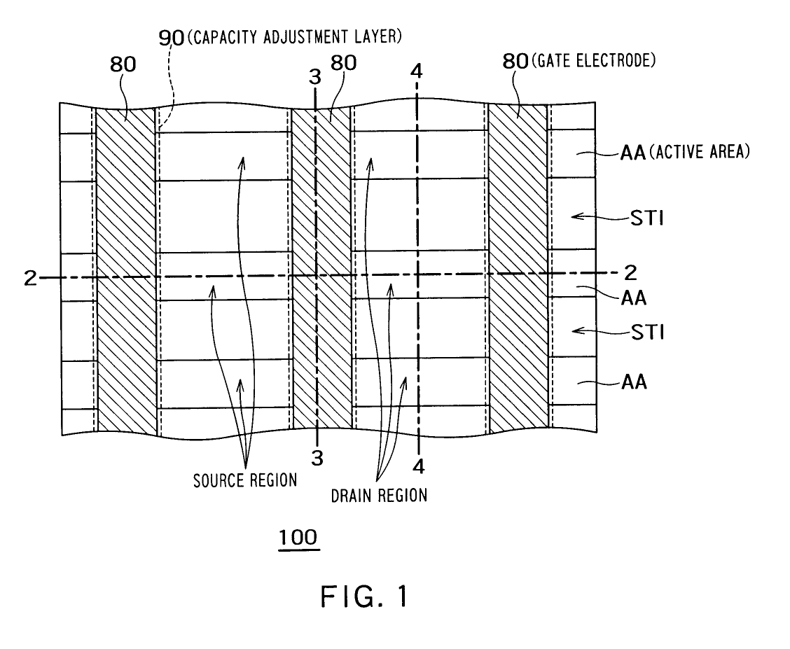

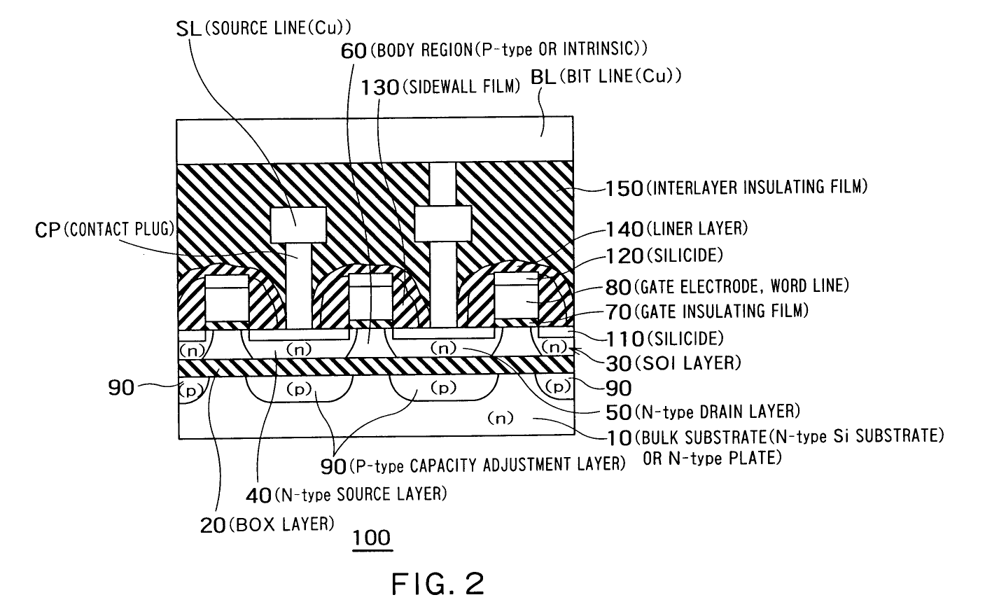

FIG. 1 is a plan view of an FBC memory device 100 according to a first embodiment of the present invention. In FIG. 1, upper layers than gate electrodes 80 are not shown. In FIG. 1, active areas AAs and STIs (Shallow Trench Isolations) serving as element isolation areas are alternately formed into stripes. The gate electrodes 80 (or word lines WLs) extend in a direction in which the active areas AAs are adjacent (in a direction orthogonal to an extension direction of the active areas AAs). The active areas AAs on both sides of the gate electrodes 80 function as source regions and drain regions, respectively. Capacity adjustment layers 90 are formed in a silicon substrate (see FIG. 2) between adjacent gate electrodes 80. The capacity adjustment layers 90 are provided to extend in parallel to the gate electrodes 80.

FIG. 2 is a cross-sectional view of the FBC memory device 100 taken along a line 2-2 of FIG. 1 (in the extension direction of the active areas AAs). The FBC memory device 100 is formed on an SOI substrate including an N-type silicon substrate or an N-type plate (hereinafter, “N substrate”) 10, a BOX layer 20 formed on the N substrate 10, and an SOI layer 30 formed on the BOX layer 20. The FBC memory device 100 includes N-type source layers 40 formed in the SOI layer 30, N-type drain layers 50 formed in the SOI layer 30, body regions 60 formed in the SOI layer 30 and each provided between one source layer 40 and one drain layer 50, gate insulating films 70 formed on the respective body regions 60, and gate electrodes 80 formed on the respective gate insulating films 70. Each of the body regions 60 is made of a P-type semiconductor or an intrinsic semiconductor, and is surrounded by one source layer 40, one drain layer 50, one gate insulating film 70, the BOX layer 20, and one STI. The body region 60 can be thereby turned into an electrically floating state and can hold data therein according to a state in which majority carriers are accumulated in the body region 60.

A silicide layer 110 is formed on a surface of each of the source layers 40 and the drain layers 50, and a silicide layer 120 is formed on an upper surface of each of the gate electrodes 80. Contact resistances with respect to the source layers 40 and the drain layers 50 and gate resistances are thereby reduced.

Sidewall films 130 are provided on both side surfaces of each of the gate electrodes 80, respectively. Further, a liner layer 140 is formed to cover up the silicide layer 120 and the sidewall films 130. An interlayer insulating film 150 is provided on the liner layer 140.

Source lines SLs are connected to the source layers 40 via contact plugs CPs, respectively. The source lines SLs extend in parallel to the gate electrodes 80. Bit lines BLs are connected to the drain layers 50 via contact plugs CPs, respectively. The bit lines BLs extend to be orthogonal to the gate electrodes 80 and the source lines SLs.

The FBC memory device 100 also includes P-type capacity adjustment layers 90. The capacity adjustment layers 90 are provided on a surface of the N substrate 10 present right under the source layers 40 and the drain layers 50. The capacity adjustment layers 90 are provided to adjust capacities of the source lines SLs and the bit lines BLs, respectively. On the other hand, the capacity adjustment layers 90 are not provided on a surface of the N substrate 10 present right under the body regions 60. Due to this, a conduction type of the surface of the N substrate 10 right under the body regions 60 remains N type. An impurity concentration of the N substrate 10 is, for example, about 1×10¹⁵/cm⁻³ and that of the capacity adjustment layers 90 is, for example, about 1×10¹⁵/cm⁻³ to 1×10¹⁶/cm⁻³.

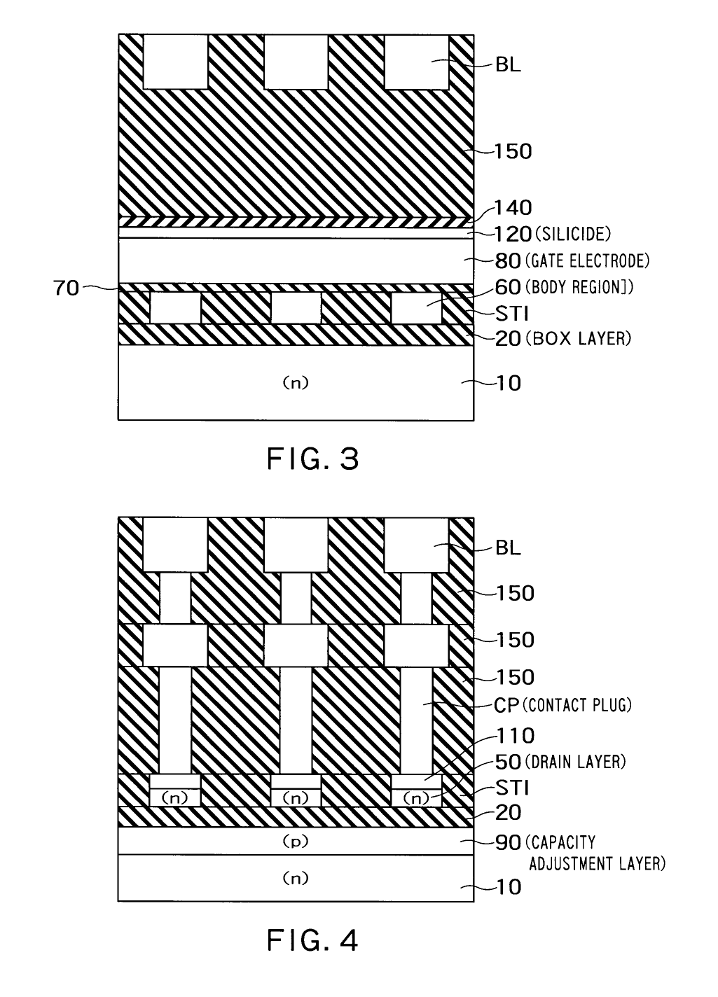

FIG. 3 is a cross-sectional view of the FBC memory device 100 taken along a line 3-3 of FIG. 1 (along the gate electrodes 80). The body regions 60 below the gate electrode 80 (the word line WL) are isolated from one another by the STIs. No P-type capacity adjustment layers 90 are present right under the body regions 60, where the N substrate 10 is provided via the BOX layer 20.

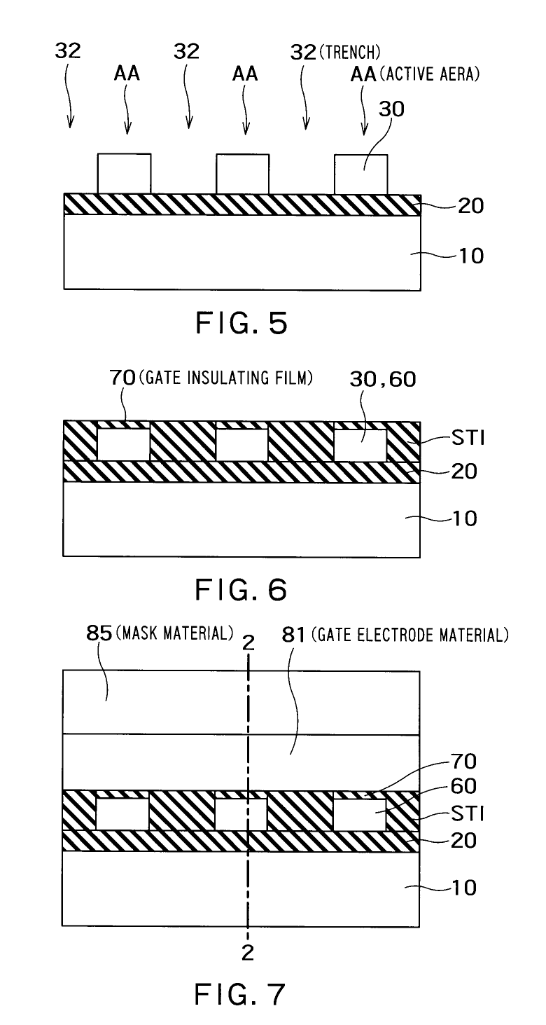

FIG. 4 is a cross-sectional view of the FBC memory device 100 taken along a line 4-4 of FIG. 1. The line 4-4 extends in the direction in which the drain layers 50 are adjacent. The P-type capacity adjustment layer 90 is provided right under the drain layers 50 via the BOX layer 20. The capacity adjustment layer 90 extends in the direction in which the drain layers 50 are adjacent. As indicated by broken lines of FIG. 1, the capacity adjustment layers 90 are introduced along the gate electrodes 80 between the adjacent gate electrodes 80.

Each of memory cells MCs of the FBC memory device 100 according to the first embodiment is an N-type FET. The FBC memory device 100 can store data in each memory cell MC according to the number of majority carriers accumulated in the body region 60 of the memory cell MC. If the memory cells MCs are N-type FETs, it is defined that a state of each memory cell MC in which the number of holes accumulated in the body region 60 is large is a state in which the memory cell MC stores therein data “1” and that a state thereof in which the number of holes accumulated in the body regions 60 is small is a state in which the memory cell MC stores therein data “0”.

To write data “1” to each of the memory cells MC, the memory cell MC is caused to operate in a saturation state. For example, a potential of the word line WL connected to the memory cell MC is biased to 1.5 V, and that of the bit line BL connected to the memory cell is biased to 1.5 V. A potential of the source line SL connected to the memory cell MC is set to a ground voltage GND (0 V). By doing so, impact ionization occurs near the drain layer 50 of the memory cell MC to thereby generate many pairs of electrons and holes. The electrons generated by the impact ionization flow into the drain layer 50 whereas the holes generated by the impact ionization are accumulated in the low-potential body region 60. If a current flowing when the holes are generated by the impact ionization becomes proportional to a forward current at a pn junction between the body region 60 and the source layer 40 of the memory cell MC, a body voltage turns into an equilibrium state. The body voltage in the equilibrium state is about 0.7 V.

To write data “0” to each memory cell MC, a potential of the bit line BL connected to the memory cell MC is reduced to negative voltage. For example, the potential of the bit line BL connected thereto is reduced to −1.5 V. By doing so, a pn junction between the body region 60 and the drain layer 50 of the memory cell MC is largely biased in a forward direction. The holes accumulated in the body region 60 are discharged to the drain layer 50, whereby data “0” is stored in the memory cell MC.

During a data read operation, i.e., to read data from each of the memory cells MCs, the word line WL connected to the memory cell MC is activated similarly to the data write operation but the potential of the bit line BL connected thereto is set lower than that during the operation for writing data “1” to the memory cell MC. For example, the potential of the word line WL is set to 1.5 V and that of the bit line BL is set to 0.2 V. The memory cell MC is caused to operate in a linear region. The memory cells MCs storing therein data “1” differ from the memory cells MCs storing therein data “0” in threshold voltage due to the difference therebetween in the number of holes accumulated in the body region 60. By detecting the threshold voltage difference, the data “1” is discriminated from the data “0”. The reason for setting the potential of the bit line BL to the low voltage during the data read operation is as follows. If the voltage of the bit line BL connected to one memory cell MC is set high to bias the memory cell MC to the saturation state, the data “0” is changed to the data “1” by the impact ionization at the time of reading the data “0”.

Generally, a constant potential (e.g., −3 V) lower than any of a source voltage, a bit voltage, and a gate voltage is applied to the N substrate 10. Accordingly, a depletion layer is generated from a surface of each P-type capacity adjustment layer 90, thus reducing the capacities between the drain layer 50 of each memory cell MC and the substrate 10, and between the source layer 40 thereof and the substrate 10. In other words, by providing the capacity adjustment layers 90 opposite in conduction type to the source layer 40 and the drain layer 50 of each memory cell MC only on the surface of the N substrate 10 present under the source layer 40 and the drain layer 50, capacities of the source lines SLs and the bit lines BLs can be substantially reduced without changing a thickness of the BOX layer 20. As a result, operating rates such as a data write rate and a data read rate are accelerated. Moreover, if the thickness of the BOX layer 20 is reduced, it is possible to suppress deceleration of the operating rates such as the data write rate and the data read rate.

On the other hand, no capacity adjustment layer 90 is provided right under the body region 60 of each memory cell MC, where only the N substrate 10 is present as it is. Accordingly, no depletion layer is generated under the body region 60. Namely, the capacity between the body region 60 and the N substrate 10 is not reduced and the signal difference (voltage difference) between the data “1” and “0” is not reduced. In other words, if the thickness of the BOX layer 20 is reduced, the signal difference can be increased accordingly.

A method of manufacturing the FBC memory device 100 according to the first embodiment will be described.

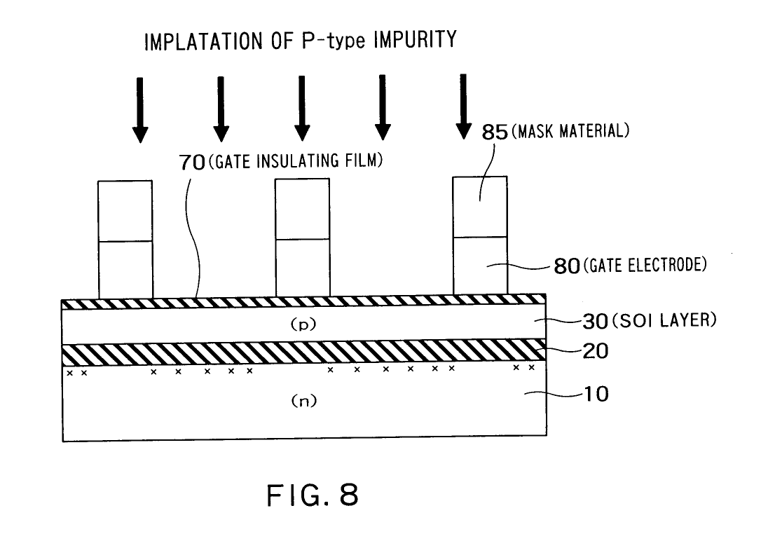

FIGS. 5 to 9 are cross-sectional views showing the method of manufacturing the FBC memory device 100 according to the first embodiment. FIGS. 5 to 7 correspond to the cross-section taken along the line 3-3 of FIG. 1 (along the gate electrodes 80). First, the SOI substrate including the N substrate 10, the BOX layer 20 provided on the N substrate 10, and the SOI layer 30 provided on the BOX layer 20 is prepared. The N substrate 10 is an N-type bulk substrate or an N-type plate. The SOI layer 30 is made of a P-type semiconductor or an intrinsic semiconductor. Next, using lithography and RIE, the SOI layer 30 present in the STI regions (element isolation regions) shown in FIG. 1 is etched. As a result, as shown in FIG. 5, the SOI layers 30 remain in the active areas AAs, and STI trenches 32 are formed between the active areas AAs. If the substrate 10 is a plate, the plate can be formed after forming the active areas AAs.

As shown in FIG. 6, the trenches 32 are filled with an insulating film (e.g., a silicon oxide film), thereby forming STIs. Next, the gate insulating films 70 are formed on the SOI layers 30 (body regions 60). The gate insulating films 70 are formed by, for example, thermally oxidizing the SOI layers 30.

As shown in FIG. 7, a gate electrode material 81 is deposited on the gate insulating films 70 and a mask material 85 is deposited on the gate electrode material 81. The gate electrode material 81 is, for example, polysilicon and the mask material 85 is, for example, a photoresist, a silicon oxide film or a silicon nitride film.

The mask material 85 is worked into a pattern of the gate electrodes 80 shown in FIG. 1. Further, using the worked mask material 85 as a mask, the gate electrode material 81 is etched by RIE. As a result, the gate electrodes 80 are formed as shown in FIG. 8. FIG. 8 corresponds to FIG. 7 or to the cross-section taken along the line 2-2 of FIG. 1.

Using the mask material 85 or the gate electrodes 80 as a mask, P-type impurity ions (e.g., boron) are implanted into the surface of the N substrate 10. At this time, the P-type impurity ions are implanted in a self-aligned fashion while using the mask material 85 or the gate electrodes 80 as the mask. Due to this, the P-type impurity ions are not implanted into the N substrate 10 present under body formation regions. Acceleration energy at this ion implantation step is adjusted so that a range of the impurities is up to or slightly short of the surface of the N substrate 10.

After removing the mask material 85 as shown in FIG. 9, annealing is performed to diffuse the P-type impurities. As a result, the P-type capacity adjustment layers 90 are formed in a self-aligned fashion on the surface of the N substrate 10 except for that right under the gate electrodes 80.

Using the gate electrodes 80 as a mask, impurity ions (e.g., phosphor or arsenic ions) opposite in conduction type to the P-type impurity ions contained in the P-type capacity adjustment layers 90 are implanted into the SOI layer 30. As a result, the source layers 40 and the drain layers 50 as shown in FIG. 2 are formed in the SOI layer 30 in a self-aligned fashion. By forming the source layers 40 and the drain layers 50, the body regions 60 are defined in the SOI layer 30.

Thereafter, the silicide layers 110 and 120, the contact plugs CPs, the source lines SLs, and the bit lines BLs are formed by well-known methods, thereby completing the FBC memory device 100. Before forming the source layers 40 and the drain layers 50, an extension layer (not shown) can be formed if it is necessary to do so. The extension layer is formed to be adjacent to the source layers 40 and the drain layers 50 and equal in conduction type to the source layers 40 and the drain layers 50.

In the first embodiment, if a thickness of each of the gate electrodes 80 is larger than a sum of the thickness of the SOI layer 30 and that of the BOX layer 20, P-type impurity ions can be implanted into the N substrate 10 using only the gate electrodes 80 as the mask at the step of forming the capacity adjustment layers 90.

In the manufacturing method according to the first embodiment, it suffices to add only the ion implantation steps and the annealing step to ordinary FBC memory device manufacturing steps as the steps of forming the capacity adjustment layers 90. Furthermore, the capacity adjustment layers 90 are formed in a self-aligned fashion using the pattern of the gate electrodes 80. Namely, there is no need to execute a lithography step and an etching step to form the capacity adjustment layers 90. Therefore, the manufacturing method according to the first embodiment can be carried out far more easily at lower cost than the manufacturing method disclosed in the Patent Document 1.

To diffuse the capacity adjustment layers 90 more widely, it is preferable to execute the ion implantation step for the capacity adjustment layers 90, the ion implantation step for the extension layer, and the ion implantation step for the source layers 40 and the drain layers 50 in this order after the formation of the gate electrodes 80.

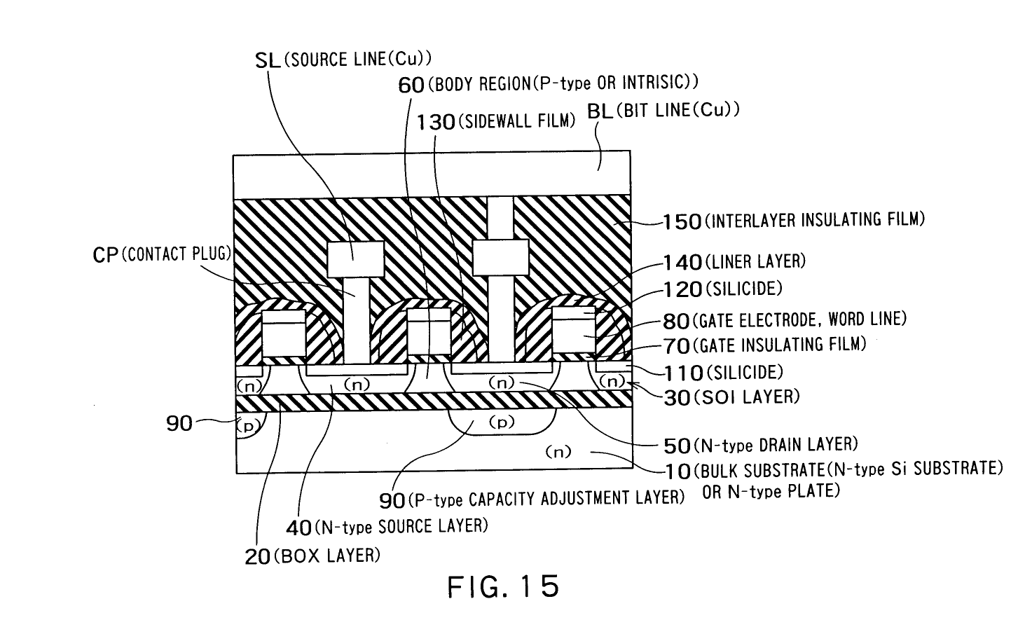

The capacity adjustment layers 90 provided under the source layers 40 can substantially reduce the capacities of the respective source lines SLs. This can give an advantage of accelerating memory cell operating rates when the source voltage is varied. If the source voltage is fixed, the capacity adjustment layers 90 can be provided only under the respective drain layers 50 and not under the respective source layers 40 as shown in FIG. 15. Even if the capacity adjustment layers 90 are provided as shown in FIG. 15, the capacities of the bit lines BLs can be substantially reduced. Therefore, the above-stated advantages of the first embodiment are not lost.

### SECOND EMBODIMENT

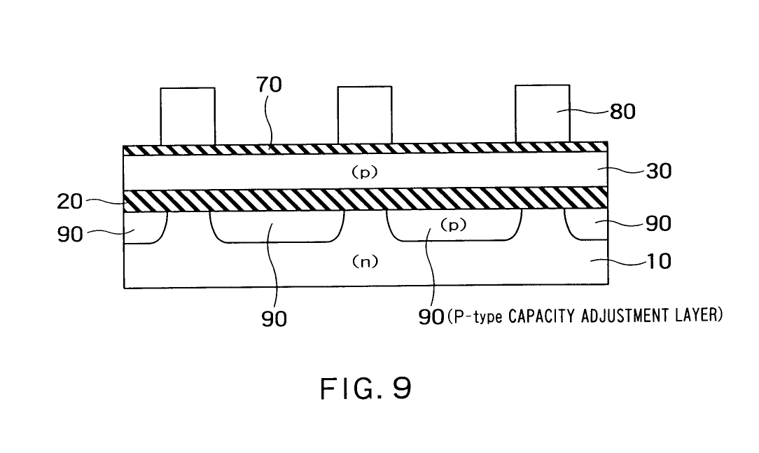

FIG. 10 is a cross-sectional view of an FBC memory device 200 according to a second embodiment of the present invention. In the FBC memory device 200, a conduction type of a silicon substrate or plate 10 is a P type (hereinafter, “P substrate”), and the P substrate 10 is opposite in conduction type to the source layers 40 and the drain layers 50 and equal in conduction type to the capacity adjustment layers 90. The other constituent elements of the FBC memory device 200 according to the second embodiment can be similar to those according to the first embodiment. While the capacity adjustment layers 90 are equal in conduction type to that of the P substrate 10, they are lower in impurity concentration than the P substrate 10. For example, an impurity concentration of the P substrate 10 is about 1×10¹⁷/cm⁻³ and that of the capacity adjustment layers 90 is about 1×10¹⁶/cm⁻³. Further, a surface of the P substrate 10 right under the body regions 60 is equal in impurity concentration to the other portions of the P substrate 10.

According to the second embodiment, the impurity concentration of the capacity adjustment layers 90 is lower than that of the P substrate 10. Due to this, if memory cells MCs operate, then depletion layers are generated from surfaces of the respective capacity adjustment layers 90, and the capacity between each drain layer 50 and the P substrate 10 and that between each source layer 40 and the P substrate 10 are reduced. Namely, by providing the capacity adjustment layers 90 opposite in conduction type to the source layers 40 and the drain layers 50 only on the surface of the P substrate 10 right under the source layers 40 and the drain layers 50, it is possible to substantially reduce capacities of the source lines SLs and the bit lines BLs without changing the thickness of the BOX layer 20. As a result, the second embodiment can exhibit the same advantages as those of the first embodiment.

A method of manufacturing the FBC memory device 200 according to the second embodiment differs from the manufacturing method according to the first embodiment in that the silicon substrate 10 is the P-type bulk substrate or P-type plate and in that N-type impurity ions are implanted in a self-aligned fashion using the gate electrodes 80 and the mask material 85 as a mask at a step of forming the capacity adjustment layers 90. The other steps of the manufacturing method according to the second embodiment can be similar to those according to the first embodiment.

The N-type impurity ions implanted at the step of forming the capacity adjustment layers 90 are, for example, phosphor or arsenic ions. The implanted impurity amount of the N-type impurities is about 1×10¹²/cm⁻² if the impurity concentration of the P substrate 10 is about 1×10¹⁷/cm⁻³.

In the second embodiment, if a thickness of each of the gate electrodes 80 is larger than a sum of the thickness of the SOI layer 30 and that of the BOX layer 20, N-type impurity ions can be implanted into the P substrate 10 using only the gate electrodes 80 as a mask at the step of forming the capacity adjustment layers 90.

In the manufacturing method according to the second embodiment similarly to the first embodiment, it suffices to add only the ion implantation steps and the annealing step to ordinary FBC memory device manufacturing steps as the steps of forming the capacity adjustment layers 90. Furthermore, the capacity adjustment layers 90 are formed in a self-aligned fashion using the pattern of the gate electrodes 80. Therefore, similarly to the manufacturing method according to the first embodiment, the manufacturing method according to the second embodiment can be carried out far more easily at lower cost than the manufacturing method disclosed in the Patent Document 1.

The capacity adjustment layers 90 provided under the source layers 40 can substantially reduce the capacities of the respective source lines SLs. This can give an advantage of accelerating memory cell operating rates when the source voltage is varied. If the source voltage is fixed, the capacity adjustment layers 90 can be provided only under the respective drain layers 50 and not under the respective source layers 40 similarly to the first embodiment. Even if the capacity adjustment layers 90 are provided as above, the capacities of the bit lines BLs can be substantially reduced. Therefore, the above-stated advantages of the second embodiment are not lost.

### THIRD EMBODIMENT

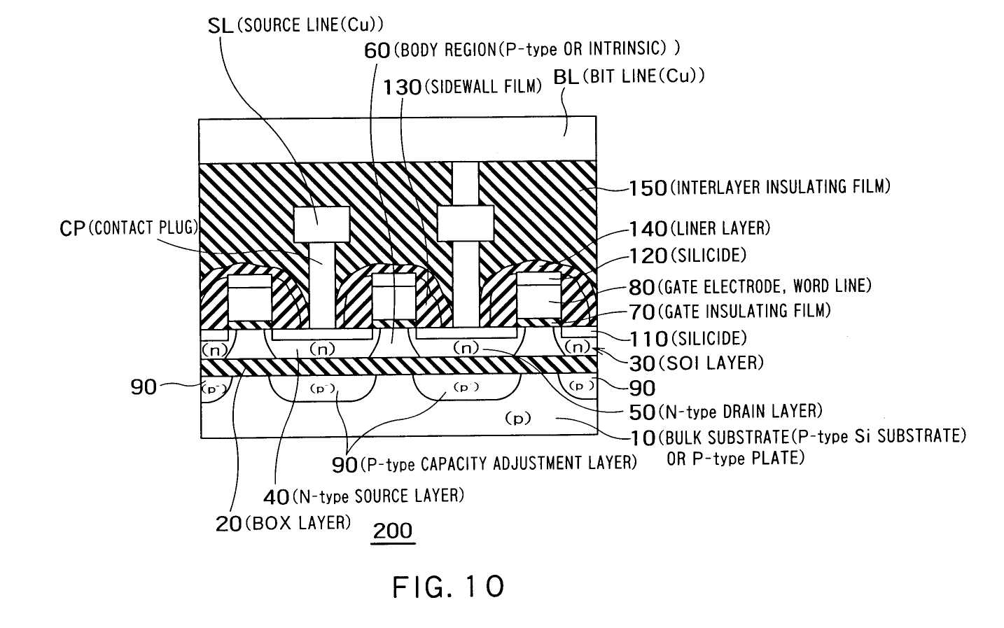

FIG. 11 is a plan view of an FBC memory device 300 according to a third embodiment of the present invention. In FIG. 11, upper layers than gate electrodes 80 are not shown. In the third embodiment, active areas AAs are formed into an island shape in a half-pitch-staggered fashion between adjacent gate electrodes 80, and are disposed in a staggered fashion. One memory cell MC is formed on one island of the active areas AAs. The other constituent elements of the FBC memory device 300 according to the third embodiment can be similar to those according to the first embodiment.

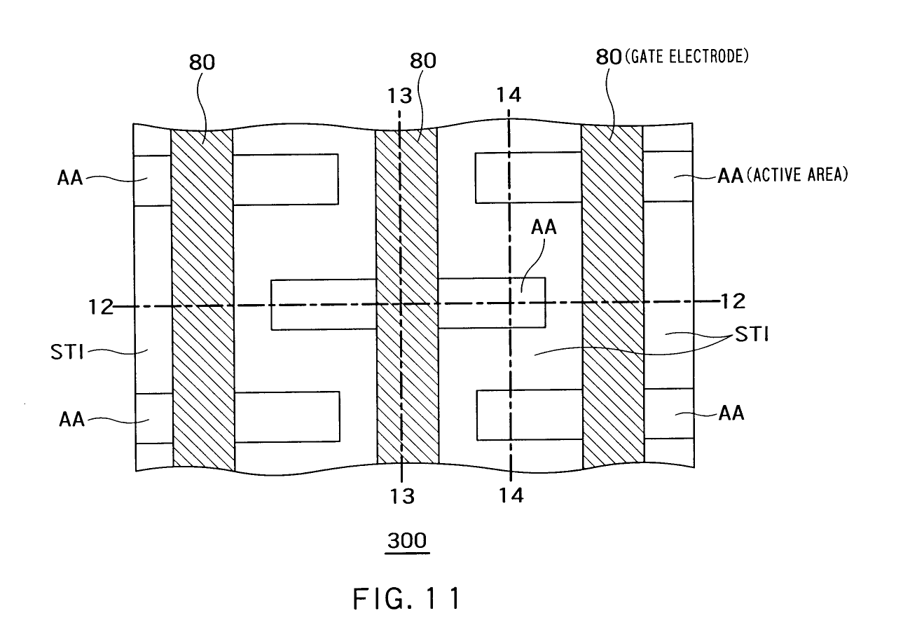

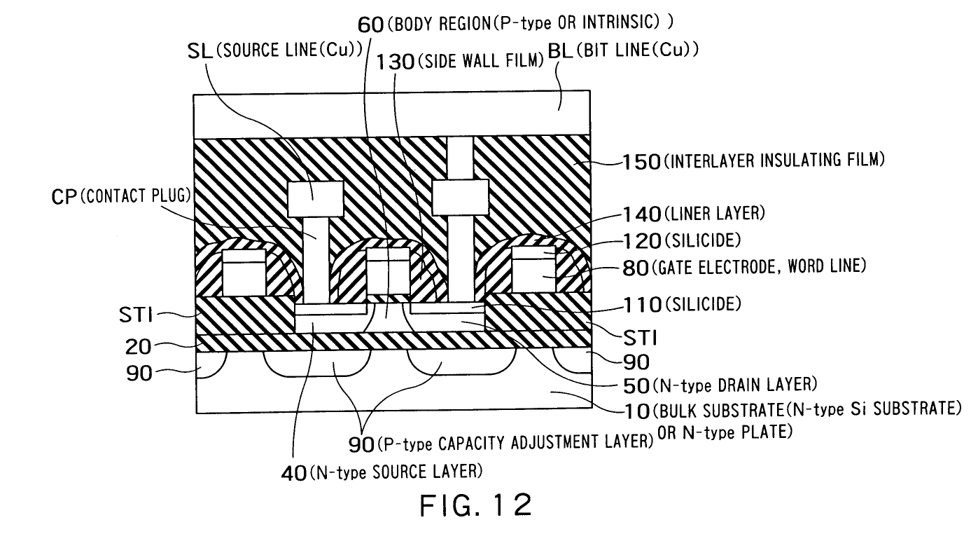

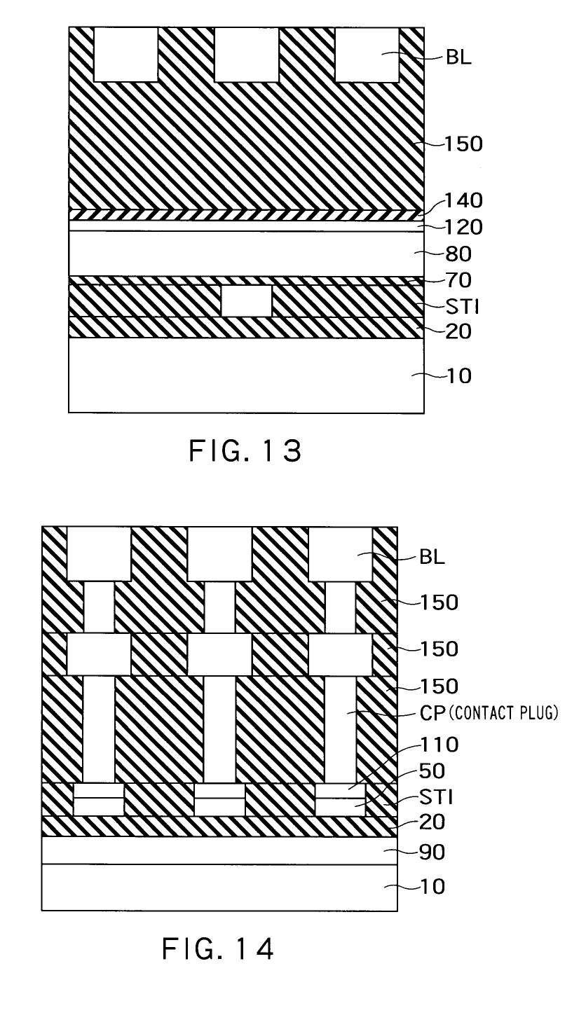

FIG. 12 is a cross-sectional view of the FBC memory device 300 taken along a line 12-12 of FIG. 11. FIG. 13 is a cross-sectional view of the FBC memory device 300 taken along a line 13-13 of FIG. 11. FIG. 14 is a cross-sectional view of the FBC memory device 300 taken along a line 14-14 of FIG. 11. The active areas AAs are staggered from each other by a half pitch between the adjacent gate electrodes 80. Due to this, one source layer 40 and one drain layer 50 are not shared between two adjacent memory cells MCs. One body region 60 is adjacent to one of the source layer 40 and the drain layer 50 whereas one STI is adjacent to the other layer.

A manufacturing method according to the third embodiment differs from that according to the first embodiment in a mask pattern using when STIs are formed. The other steps of the manufacturing method according to the third embodiment can be similar to those according to the first embodiment. The third embodiment can exhibit the same advantages as those of the first embodiment.

The third embodiment can be combined with the second embodiment. Namely, in the third embodiment, the substrate 10 can be either the P-type bulk substrate or P-type plate. In this case, the capacity adjustment layers 90 are lower in impurity concentration than the substrate 10. Therefore, the third embodiment can exhibit the same advantages as those of the second embodiment.

The capacity adjustment layers 90 provided under the source layers 40 can substantially reduce the capacities of the respective source lines SLs. This can give an advantage of accelerating memory cell operating rates when the source voltage is varied. If the source voltage is fixed, the capacity adjustment layers 90 can be provided only under the respective drain layers 50 and not under the respective source layers 40 similarly to the first embodiment. Even if the capacity adjustment layers 90 are provided as above, the capacities of the bit lines BLs can be substantially reduced. Therefore, the above-stated advantages of the third embodiment will not be lost.

1. A semiconductor memory device comprising:
a semiconductor substrate;
a buried insulating film provided on the semiconductor substrate;
a semiconductor layer provided on the buried insulating film;
an N-type source layer formed in the semiconductor layer;
an N-type drain layer formed in the semiconductor layer;
a body region formed in the semiconductor layer to be provided between the source layer and the drain layer, the body region being in an electrically floating state and holding data according to a state of accumulating majority carriers in the body region;
a gate insulating film provided on the body region;
a gate electrode provided on the gate insulating film; and
a P-type diffusion layer provided on a surface of the semiconductor substrate present under the drain layer, wherein
a conduction type of a surface of the semiconductor substrate present under the body region is an N type.

2. The semiconductor memory device according to claim 1, wherein
the diffusion layer is provided on a surface of the semiconductor substrate present under both the source layer and the drain layer.

3. The semiconductor memory device according to claim 1, further comprising:
a source line connected to the source layer, and extending in parallel to the gate electrode; and
a bit line extending to be orthogonal to the gate electrode and the source line, wherein
the diffusion layer is provided to extend in parallel to the gate electrode and the source line.

4. The semiconductor memory device according to claim 1, wherein
active areas in which the semiconductor layer are present are formed into an island shape in a staggered fashion.

5. The semiconductor memory device according to claim 1, wherein
the source layer, the drain layer, the body region, and the gate electrode constitute a floating body cell.

6. A semiconductor memory device comprising:
a P-type semiconductor substrate;
a buried insulating film provided on the semiconductor substrate;
a semiconductor layer provided on the buried insulating film;
an N-type source layer formed in the semiconductor layer;
an N-type drain layer formed in the semiconductor layer;
a body region formed in the semiconductor layer to be provided between the source layer and the drain layer, the body region being in an electrically floating state and holding data according to a state of accumulating majority carriers in the body region;
a gate insulating film provided on the body region;
a gate electrode provided on the gate insulating film; and
a P-type diffusion layer provided on a surface of the semiconductor substrate present under the drain layer, the P-type diffusion layer being lower in impurity concentration than the semiconductor substrate, wherein
a conduction type of a surface of the semiconductor substrate present under the body region is same conduction type as the other part of the semiconductor substrate.

7. The semiconductor memory device according to claim 6, wherein
the diffusion layer is provided on a surface of the semiconductor substrate present under both the source layer and the drain layer.

8. The semiconductor memory device according to claim 6, further comprising:
a source line connected to the source layer, and extending in parallel to the gate electrode; and
a bit line extending to be orthogonal to the gate electrode and the source line, wherein
the diffusion layer is provided to extend in parallel to the gate electrode and the source line.

9. The semiconductor memory device according to claim 6, wherein
active areas in which the semiconductor layer are present are formed into an island shape in a staggered fashion.

10. The semiconductor memory device according to claim 6, wherein
the source layer, the drain layer, the body region, and the gate electrode constitute a floating body cell.

11. A method of manufacturing a semiconductor memory device, comprising:
preparing a semiconductor substrate including a semiconductor substrate, a buried insulating film provided on the semiconductor substrate, and a semiconductor layer provided on the buried insulating film;
forming a gate insulating film on the semiconductor layer;
depositing a gate electrode material on the gate insulating film;
depositing a mask material on the gate electrode material;
working the mask material into a gate electrode pattern;
forming a gate electrode by etching the gate electrode material using the mask material as a mask;
forming a diffusion layer in the semiconductor substrate in a self-aligned fashion by implanting an impurity into a surface of the semiconductor substrate using the mask material or the gate electrode as a mask; and
forming a source layer and a drain layer in the semiconductor layer in a self-aligned fashion by implanting an impurity opposite in conduction type to the impurity of the diffusion layer into the semiconductor layer using the gate electrode as a mask.

12. The semiconductor memory device according to claim 11, wherein
the source layer, the drain layer, the body region, and the gate electrode constitute a floating body cell.
